(19) United States
(12) Patent Application Publication
(10) Pub. No.: US 2009/0071706 A1
(43) Pub. Date: Mar. 19, 2009

(54) METHOD FOR PRODUCING MULTILAYERED WIRING SUBSTRATE, MULTILAYERED WIRING SUBSTRATE, AND ELECTRONIC APPARATUS

(75) Inventors: Tsuyoshi SHINTATE, Sakata (JP); Toshimitsu HIRAI, Hokuto (JP); Jun YAMADA, Shiojiri (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/191,358

(22) Filed: Aug. 14, 2008

(30) Foreign Application Priority Data
Sep. 18, 2007 (JP) 2007-241015

(51) Int. Cl. H05K 1/11; B32B 37/14

(52) U.S. Cl. 174/262; 156/281

(57) ABSTRACT

A method for producing a multilayered wiring substrate includes forming a lyophobic area on a first conductive layer, forming an insulating layer with an opening portion on the first conductive layer by applying a functional liquid containing an insulating layer forming material on a periphery of the lyophobic area, laminating the first conductive layer and a second conductive layer via the insulating layer, and electrically connecting the first and the second conductive layers to each other via the opening portion formed in the insulating layer. In the method, when forming the insulating layer, the functional liquid is applied such that an angle of a portion of the functional liquid in contact with the lyophobic area becomes larger than a forward contact angle of the functional liquid, thereby allowing a position of the portion of the functional liquid in contact with the lyophobic area to move inside the lyophobic area to form the opening portion having an opening size smaller than a size of the lyophobic area.

### BACKGROUND

1. Technical Field

The present invention relates to a method for producing a multilayered wiring substrate, a multilayered wiring substrate, and an electronic apparatus.

2. Related Art

There are techniques being vigorously developed to discharge a liquid containing a desired compound material by using a liquid droplet discharging method (an inkjet method) and to allow the liquid to land in a predetermined position so as to form a predetermined material pattern. The pattern forming techniques enable a minute amount of the liquid to be applied in the predetermined position according to a resolution of an inkjet head used, thus being advantageous in that the techniques can form minute patterns. For example, when forming a minute wiring pattern on a circuit substrate, a wiring material or a solution composed of the wiring material is applied thereon to form the wiring pattern.

However, the techniques tend to be influenced by properties of a substrate surface where the liquid is applied. For example, when a liquid-landing area is easily wettable (lyophilic) to the liquid, a liquid droplet applied can wettingly spread into a shape larger than desired. Conversely, when the landing area is unwettable (lyophobic) to the liquid, liquid aggregation occurs thereon, resulting in formation of a bulge (a liquid lump), which inhibits formation of a desired shape.

Meanwhile, in order to meet a market demand for miniaturization and multifunctionality of electronic apparatuses in the recent years, high-density and highly integrated electronic circuits have become more available. One of techniques for producing a highly integrated electronic circuit is to employ a multilayered wiring structure in the circuits. An electronic circuit employing the multilayered wiring structure is not only two-dimensionally but vertically formed by laminating circuit substrates, thereby achieving formation of a high performance circuit in a small installation area. When employing the multilayered wiring structure, wiring patterns formed on individual layers are connected to each other via contact holes formed in insulating films between the layers. In general, electronic circuits with the multilayered wiring structure require minute contact holes due to a demand for high-density and high-integration circuits.

As a technique for forming a minute contact hole, JP-A-2003-282561 and JP-A-2006-140437 disclose a contact-hole forming method by using a liquid droplet discharging method. Specifically, when a liquid containing an insulating-film forming material (an insulating ink) is applied by the liquid droplet discharging method to form an interlayer insulating film, the insulating ink is not applied only in a contact-hole forming area, so as to provide a non-insulating-film area that is to be used as a contact hole.

In the above method, however, for example, when forming a contact hole in a highly wettable area such as a metallic wiring, it is difficult to desirably control a size of the contact hole, since the insulating ink applied tends to wettingly spread outside a desired area.

### SUMMARY

The present invention has been accomplished in view of the problem. An advantage of the invention is to provide a method for producing a multilayered wiring substrate allowing a position and a size of a contact hole to be excellently controlled. Another advantage of the invention is to provide a multilayered wiring substrate including a minute contact hole by using the producing method. Still another advantage of the invention is to provide an electronic apparatus including the multilayered wiring substrate thus produced.

A method for producing a multilayered wiring substrate according to a first aspect of the invention includes forming a lyophobic area on a first conductive layer, forming an insulating layer with an opening portion on the first conductive layer by applying a functional liquid containing an insulating layer forming material on a periphery of the lyophobic area, laminating the first conductive layer and a second conductive layer via the insulating layer, and electrically connecting the first and the second conductive layers to each other via the opening portion of the insulating layer. In the method, when forming the insulating layer, the functional liquid is applied such that an angle of a portion of the functional liquid in contact with the lyophobic area becomes larger than a forward contact angle of the functional liquid, thereby allowing a position of the portion of the functional liquid in contact with the lyophobic area to move inside the lyophobic area to form the opening portion having an opening size smaller than a size of the lyophobic area.

In the method of the first aspect, first, a lyophobic-material containing liquid (a lyophobic ink) is applied on a region larger than a region of the first conductive layer overlapping with the opening portion (a contact hole) to be formed, so as to form the lyophobic area. The lyophobic ink is applied by using the liquid droplet discharging method, so that the lyophobic area can be formed accurately at a desired position.

Next, when applying the functional liquid containing the insulating-layer forming material (an insulating ink), the insulating ink is repelled due to a lyophobic property of the formed lyophobic area, and once located on a region excluding the lyophobic area to be applied in a condition where the region overlapping with the lyophobic area is opened. In this case, when the insulating ink is applied such that the angle of the portion of the ink in contact with the lyophobic area (the contact angle) becomes larger than the forward contact angle of the ink, the ink flows inside the lyophobic area without stopping at an outer edge of the area to wettingly spread. In the first aspect of the invention, the insulating ink is applied by the liquid droplet discharging method that enables a precise control of application of the ink. Thus, precisely controlling the application of the ink enables a precise control of the flow of the insulating ink to an inside of the lyophobic area. Additionally, the insulating ink is applied until the ink reaches the region overlapping with the contact hole to be formed, whereby the insulating ink is located on the region excluding the region overlapping with the contact hole, thus resulting in formation of the insulating layer with the contact hole. Furthermore, the second conductive layer is provided to be connected to the first conductive layer via the contact hole formed in the insulating layer, thereby enabling formation of a multilayered wiring substrate.

In the multilayered wiring substrate produced by the method of the first aspect, a position of the lyophobic area determines an accurate position of the contact hole, and the contact angle controls the flow of the insulating ink to the inside of the lyophobic area. This can facilitate formation of the contact hole having the opening size smaller than the size of the lyophobic area. Consequently, the method of the first aspect can accurately control the position and the size of a contact hole to form a multilayered wiring substrate.

In the method according to the first aspect, preferably, the lyophobic area is formed by a liquid droplet discharging method.

In this manner, the lyophobic area having a minute size can be easily formed, thereby enabling formation of a minute contact hole in accordance with the minute lyophobic area formed.

In the method according to the first aspect, preferably, when forming the insulating layer, an applying amount of the functional liquid controls the angle of the portion of the functional liquid in contact with the lyophobic area.

Usually, when a liquid is further added to a droplet of the liquid applied at an angle (a static contact angle) on a surface of a solid member, the droplet is crashed and deformed by the liquid's own weight. Due to the deformation, the contact angle is changed. When the liquid is added until the contact angle of the liquid becomes larger than a forward contact angle of the liquid, the deformation by the liquid's weight is reduced, and then, the droplet wettingly spreads until the contact angle becomes equal to the forward contact angle. Therefore, controlling the applying amount of the insulating ink enables the ink to be applied such that the contact angle becomes larger than the forward contact angle, thus facilitating the formation of the contact hole.

Additionally, in the method according to the first aspect, preferably, when forming the insulating layer, the functional liquid is heated to control the angle of the portion of the functional liquid in contact with the lyophobic area.

The contact angle of the liquid applied on the surface of the solid member is changed by a temperature of the liquid. As the liquid temperature increases, the forward contact angle reduces, whereas as the liquid temperature reduces, the forward contact angle increases. Accordingly, increasing the temperature of the insulating ink applied at a predetermined contact angle leads to a change in the forward contact angle of the ink. When the contact angle becomes equal to or larger than the forward contact angle, the ink begins to flow. Consequently, controlling the temperature of the insulating ink can facilitate changing of the contact angle, thereby enabling easy control of the flow of the insulating ink to the inside of the lyophobic area.

In the method according to the first aspect, preferably, the lyophobic material includes at least one of a silane-containing compound and a fluoroalkyl-containing compound.

This ensures that the lyophobic material exhibits a sufficiently lyophobic property, thereby enabling formation of a favorable lyophobic pattern and a favorable lyophobic area.

In the method according to the first aspect, preferably, the lyophobic material forms a self-assembled film on a surface where the lyophobic material is located.

In this manner, when the lyophobic material is applied, a self-assembly of the material immediately causes formation of a monomolecular film on the applied surface, thereby enabling expression of a highly lyophobic property. This can facilitate formation of the lyophobic pattern and the lyophobic area.

Additionally, in the method according to the first aspect, preferably, the lyophobic material is a polymeric precursor that includes the lyophobic area, and the formation of the lyophobic area includes heating and polymerizing the lyophobic material.

In this manner, heating and polymerizing the precursor can further ensure the expression of the lyophobic property.

Additionally, in the method according to the first aspect, preferably, the insulating-layer forming material is a photo-curing resin.

In general, photo-curing resins exhibit a small curing shrinkage. Thus, using such a photo-curing resin facilitates formation of a contact hole having a desired shape. Additionally, a short-time light-irradiation enables curing of the resin, thus preventing flow and deformation of the applied insulating-layer forming material during curing process. This enables a high-precision control of the shape and the size of the contact hole. Furthermore, the resin can be cured by the short-time light-irradiation to form the contact hole. Accordingly, as compared to thermosetting resins, photo-curing resins can be used with a good work efficiency, thus improving productivity.

A multilayered wiring substrate according to a second aspect of the invention includes a first conductive layer having a lyophobic area formed thereon, a second conductive layer electrically connected to the first conductive layer via a contact hole, and an insulating layer having the contact hole formed therein. In the substrate, the contact hole is located on the lyophobic area of the first conductive layer and has an opening size smaller than a size of the lyophobic area, as well as an angle formed by a side wall of the contact hole and the lyophobic area includes an angle equal to a forward contact angle between a liquid containing an insulating-layer forming material and the lyophobic area.

The above structure can provide a highly integrated multilayered wiring substrate including conductive layers connected to each other via minute contact holes.

Furthermore, an electronic apparatus according to a third aspect of the invention includes the multilayered wiring substrate produced by the method according to the first aspect of the invention.

The electronic apparatus of the third aspect is miniaturized by employing the highly integrated wiring substrate with the conductive layers connected to each other via the minute contact holes.

### BRIEF DESCRIPTION OF THE DRAWINGS

The invention will be described with reference to the accompanying drawings, wherein like numbers reference like elements.

FIG. 1 is a schematic structural view of a liquid droplet discharging apparatus.

FIG. 2 is a sectional view of a liquid droplet discharging head included in the liquid droplet discharging apparatus.

FIG. 3 is a schematic view showing a method for forming a pattern by a liquid droplet discharging method.

FIGS. 4A to 4C are schematic views showing how a liquid droplet wettingly spreads.

FIG. 5 is a sectional view showing a multilayered wiring substrate according to an embodiment of the invention.

FIGS. 6A and 6B are step views illustrating a method for producing the multilayered wiring substrate of the embodiment.

FIGS. 7A and 7B are step views illustrating the method for producing the multilayered wiring substrate of the embodiment.

FIGS. 8A and 8B are step views illustrating the method for producing the multilayered wiring substrate of the embodiment.

FIGS. 9A and 9B are step views illustrating the method for producing the multilayered wiring substrate of the embodiment.

FIG. 10 is a sectional view showing a multilayered wiring substrate according to a second embodiment of the invention.

FIG. 11 is a perspective view showing an example of an electronic apparatus.

### DESCRIPTION OF EXEMPLARY EMBODIMENTS

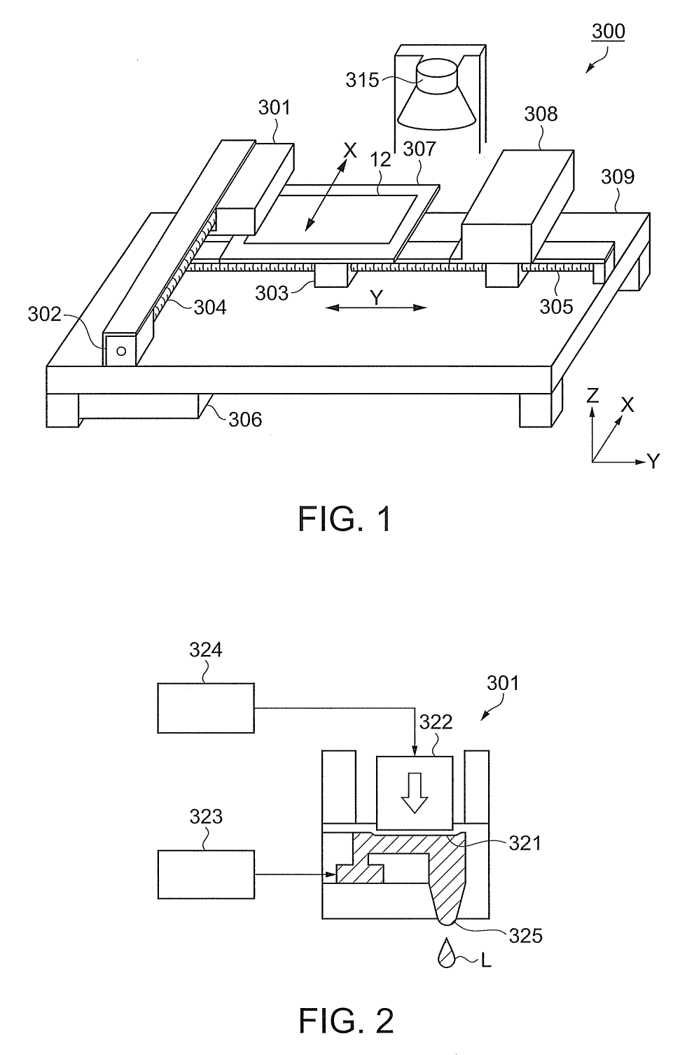

Hereinafter, a description will be given of a method for producing a multilayered wiring substrate according to embodiments of the invention by referring to FIGS. 1 to 11. Each of the drawings referred to below shows constituent members having film thicknesses, dimensional ratios, and the like changed as needed to make the drawings understandable.

### Liquid Droplet Discharging Head

First will be described a liquid droplet discharging apparatus used in a method for producing a print wiring substrate according to a first embodiment of the invention, with reference to FIGS. 1 and 2. For the embodiment, the liquid droplet discharging apparatus is used to form a solder resist film. FIG. 1 is a schematic structural view of the liquid droplet discharging apparatus. To describe the apparatus, an XYZ orthogonal coordinate system will be referred to to show positional relationships among constituent members. A predetermined direction on a horizontal plane is referred to as an X-axis direction; a direction orthogonal to the X-axis direction on the horizontal plane is referred to as a Y-axis direction; and a direction vertical to the horizontal plane is referred to as a Z-axis direction. In the present embodiment, the X-axis direction is a non-scanning direction of a liquid droplet discharging head described below, and the Y-axis direction is a scanning direction of the head.

A liquid droplet discharging apparatus 300 used for the embodiment discharges a droplet L on a substrate 12 from a liquid droplet discharging head 301. The liquid droplet discharging apparatus 300 includes the liquid droplet discharging head 301, an X-direction driving axis 304, a Y-direction guide axis 305, a controlling device 306, a stage 307, a cleaning mechanism 308, a base 309, and a heater 315.

The liquid droplet discharging head 301 is of a multi-nozzle type having a plurality of discharging nozzles, and a longitudinal direction of the head corresponds to the X-axis direction. The discharging nozzles are arranged at an equal distance from each other in the X-axis direction on a lower surface of the liquid droplet discharging head 301. The discharging nozzles of the liquid droplet discharging head 301 discharge the droplet L of a liquid on the substrate 12 supported by the stage 307. In this case, the liquid that includes a lyophobic material is referred to as a lyophobic ink L1, and the liquid used as a functional liquid that includes an insulating material is referred to as an insulating ink L2.

The X-direction driving axis 304 is immovably fixed to the base 309 and connected to an X-direction driving motor 302. The X-direction driving motor 302 is a stepping motor or the like and rotates the X-direction driving axis 304 when the controlling device 306 supplies an X-direction driving signal. When the X-direction driving axis 304 is rotated, the liquid droplet discharging head 301 is moved in the X-axis direction.

The Y-direction guide axis 305 is immovably fixed to the base 309 and connected to the stage 307 via a Y-direction driving motor 303. The Y-direction driving motor 303 is a stepping motor or the like, and moves the stage 307 in the Y direction along the Y-direction guide axis 305 when the controlling device 306 supplies a Y-direction driving signal.

The controlling device 306 applies a voltage for controlling discharging of the liquid droplet L to the liquid droplet discharging head 301. Additionally, the controlling device 306 supplies, to the X-direction driving motor 302, a driving pulse signal that controls an X-direction movement of the liquid droplet discharging head 301, as well as supplies, to the Y-direction driving motor 303, a driving pulse signal that controls a Y-direction movement of the stage 307. Furthermore, the controlling device 306 also controls turn-on and turn-off of the heater 315 described below.

The stage 307 supports the substrate 12 described below to place the liquid on the substrate 12 by the liquid droplet discharging apparatus 300 and includes a not-shown fixing mechanism to fix the substrate 12 in a reference position. The stage 307 also has the Y-direction driving motor 303 on a surface of the stage opposite to a surface thereof to which the substrate 12 is fixed.

The cleaning mechanism 308 cleans the liquid droplet discharging head 301 and includes a not-shown Y-direction driving motor. Driving the Y-direction driving motor allows the cleaning mechanism 308 to move along the Y-direction guide axis 305. The controlling device 306 controls also the movement of the cleaning mechanism 308.

The heater 315 is a unit that thermally processes the substrate 12 by lamp annealing to evaporate and dry a solvent contained in the liquid droplet L applied on the substrate 12.

The liquid droplet discharging apparatus 300 discharges the liquid droplet L on the substrate 12 while allowing the liquid droplet discharging head 301 and the stage 307 supporting the substrate 12 to perform relative scanning operation therebetween. In the present embodiment, the discharging nozzles of the liquid droplet discharging head 301 are provided in parallel to each other with a predetermined distance from each other in the X direction as the non-scanning direction. In FIG. 1, the liquid droplet discharging head 301 is located at a position perpendicular to a direction in which the substrate 12 moves. However, alternatively, the discharging head 301 may be located so as to intersect with the moving direction of the substrate 201 by adjusting an angle of the discharging head 301. In this manner, a pitch between the nozzles can be adjusted by adjusting the angle of the discharging head 301. Additionally, a distance between the substrate 12 and the nozzle surface may be arbitrarily adjusted.

FIG. 2 is a sectional view of the liquid droplet discharging head 301.

The liquid droplet discharging head 301 includes a piezo element 322 adjacent to a liquid chamber 321 that stores the liquid. The liquid is supplied into the liquid chamber 321 via a liquid supplying system 323 that includes a material tank storing the liquid.

The piezo element 322 is connected to a driving circuit 324 via which a voltage is applied to the piezo element 322 to deform the element. This leads to deformation of the liquid chamber 321 and thereby to an increase of a pressure inside the chamber, thus causing the liquid droplet L to be discharged from the nozzles 325. In this case, a value of the voltage applied is changed to control a distortion amount of the piezo element 322 so as to control the amount of the liquid discharged. Additionally, a frequency of the applied voltage is changed to control a distortion speed of the piezo element 322. The liquid droplet discharging method using the piezo system does not apply heat to material. Therefore, the method has an advantage that there is hardly any influence on a composition of the material.

Other than an electro-mechanical conversion system as described above, examples of a discharging technique in the liquid droplet discharging method include an electrification control system, a pressure-applying vibration system, an electro-thermal conversion system, and an electrostatic attraction system. In the electrification control system, electric charge is applied to a material by a charging electrode, and the material flies in a direction controlled by a deflecting electrode, thereby allowing the material to be discharged from nozzles. In the pressure-applying vibration system, for example, an ultra-high voltage of approximately 30 kg/cm² is applied to a material to discharge the material toward a tip portion of a nozzle. When no control voltage is applied, the material moves straightly to be discharged from the nozzle. When a control voltage is applied, electrostatic repulsion occurs in material particles, so that the material is scattered and not discharged from the nozzle.

Additionally, in the electro-thermal conversion system, a heater provided in a material-storing space is used to rapidly evaporate a material to generate bubbles, whereby the material in the space is discharged by a pressure of the bubbles. In the electrostatic attraction system, a minute pressure is applied into the material-storing space to form a meniscus of the material in a nozzle. In that condition, electrostatic attraction is applied to draw out the material. Other than those, it is also possible to apply techniques such as a system that uses a viscosity change in a liquid by an electric field and a system that allows a material to fly by discharging sparks. The liquid droplet discharging method is advantageous in that there is no waste in the use of the material and that an intended amount of the material can be appropriately provided in an intended position. An amount of a single droplet of the liquid material (a fluid) discharged by the liquid droplet discharging method may be in a range of 1 to 300 nanograms, for example.

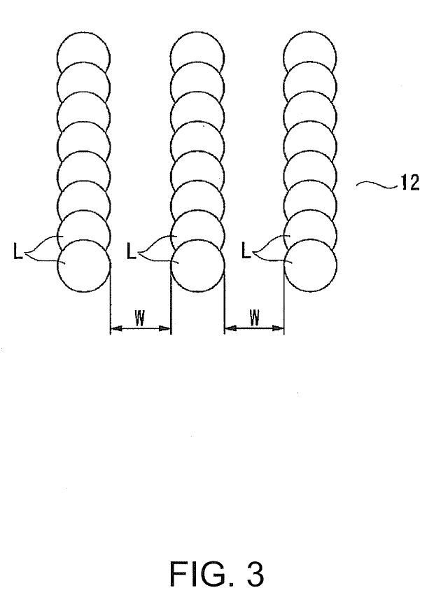

FIG. 3 is a schematic view showing a method for forming a pattern made of droplets of the liquid L applied by the liquid droplet discharging method. The liquid droplets L consecutively discharged from the liquid droplet head 301 land on a surface of the substrate 12. In this case, the liquid droplets L are discharged and applied at positions where adjacent droplets overlap each other. Thereby, a single scanning operation by the liquid droplet discharging head 301 and the substrate 12 allows formation of a continuous pattern drawn by the liquid droplets L applied. In addition, the amount of the liquid droplets L discharged and the pitch between the adjacent liquid droplets L can control formation of a desired pattern. In FIG. 3, the applied pattern is a linearly drawn pattern. However, without providing any space between the adjacent applied patterns (a width W shown in the drawing), the liquid droplets L can be applied into a plate-like pattern.

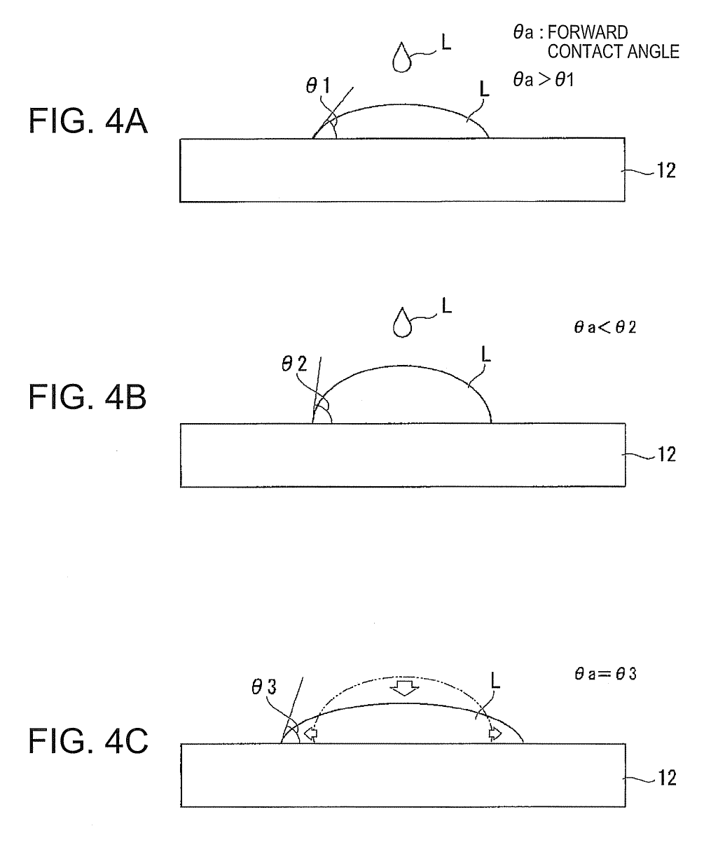

Next, FIGS. 4A to 4C are schematic diagrams each showing a relationship between the liquid droplet applied and a contact angle of the droplet. A simple description will be given of how the liquid droplet flows, by referring to the drawings, where it is shown how the liquid droplet flows as the amount of the droplet applied is increased.

In the drawings, the liquid droplet L is placed on a surface of the substrate 12. The liquid on the substrate 12 has a static contact angle (hereinafter as “contact angle”) θ1 (FIG. 4A). As the liquid is further added to the droplet L, the placed liquid is crashed and deformed by its own weight. In accordance with the deformation of the liquid, the contact angle θ1 changes to an angle θ2 (FIG. 4B). Then, when the deformation proceeds until the contact angle θ2 becomes larger than a forward contact angle θa, the liquid droplet L begins to flow. When adding the liquid until the contact angle of the droplet on the substrate 12 becomes larger than the forward contact angle θa, the deformation by the weight of the droplet itself is reduced, and thus, the droplet L wettingly spreads. When the droplet L wettingly spreads until a contact angle Θ3 of the droplet L becomes equal to the forward contact angle θa, the droplet L ceases to flow (FIG. 4C). Accordingly, the applied liquid wettingly spreads under the condition that the contact angle between the liquid droplet L and the surface of the substrate 12 is larger than the forward contact angle of the droplet L.

### Lyophobic Material

Next will be described a lyophobic area that is closely related to the contact angle on a solid surface as described above. The lyophobic area provided in the embodiment is made of a lyophobic material. Examples of the lyophobic material to be used in the embodiment include silane compounds, fluoroalkyl group-containing compounds, fluororesins (fluorine-containing resins), and mixtures of those compounds.

The silane compounds are expressed by a general formula (1):

R¹SiX¹X²X³ (1)

In the above formula, R¹ represents an organic group; X¹ represents —OR² or —Cl; X² and X³ represent —OR², —R³, or —Cl; R² represents an alkyl group having 1 to 4 carbons; and R³ represents a hydrogen atom or an alkyl group having 1 to 4 carbons. Alternatively, X¹, X², and X³ may be the same as or different from each other. Thus, the lyophobic material used in the embodiment may be a single kind or two or more kinds of the silane compounds expressed by the formula (1).

In the silane compounds expressed by the general formula (1), a silane atom is substituted by an organic group, and other bonds are substituted by alkoxy groups, alkyl groups, or chlorine groups. For example, the organic group R¹ may be a phenyl group, a benzyl group, a phenethyl group, a hydroxyphenyl group, a chlorophenyl group, an aminophenyl group, a naphthyl group, an anthrenyl group, a pyrenyl group, a thienyl group, a pyrrolyl group, a cyclohexyl group, a cyclohexenyl group, a cyclopentyl group, a cyclopentenyl group, a pyridinyl group, a methyl group, an ethyl group, an n-propyl group, an isopropyl group, an n-butyl group, an isobutyl group, a sec-butyl group, a tert-butyl group, an octadecyl group, an n-octyl group, a chloromethyl group, a methoxyethyl group, a hydroxyethyl group, an aminoethyl group, a cyano group, a mercaptopropyl group, a vinyl group, an allyl group, an acryloxyethyl group, a metacryloxyethyl group, a glycydoxypropyl group, or an acetoxy group.

The alkoxy group and the chlorine group represented by —OR² are functional groups for forming an Si—O—Si bond, and are hydrolyzed with water and desorbed as an alcohol or an acid. Examples of the alkoxy group include a methoxy group, an ethoxy group, an n-propoxy group, an isopropoxy group, an n-butoxy group, an isobutoxy group, a sec-butoxy group, and a tert-butoxy group. Preferably, the alkoxy group has 1 to 4 carbons, since desorbed alcohol molecules have a relatively small molecular weight and thus can be easily removed, thereby suppressing a density reduction of a film to be formed.

The silane compounds expressed by the general formula (1) may be dimethyl dimethoxysilane, diethyl diethoxysilane, 1-propenylmethyldichlorosilane, propyldimethyldichlorosilane, propylmethyldichlorosilane, propyltrichlorosilane, propyltriethoxysilane, propyltrimethoxysilane, styrylethyl trimethoxysilane, tetradecyl trichlrosilane, 3-thiocyanate propyltriethoxysilane, p-tolyldimethylchlorosilane, p-tolylmethyldichlorosilane, p-tolyltrichlorosilane, p-tolyltrimethoxysilane, p-tolyltriethoxysilane, di-n-propyldi-n-propoxysilane, diisopropyl diisopropoxysilane, di-n-butyldi-n-butyloxysilane, di-sec-butyldi-sec-butyloxysilane, di-t-butyldi-t-butyloxysilane, octadecyltrichlorosilane, octadecylmethyl diethoxysilane, octadecyltriethoxysilane, octadecyltrimethoxysilane, octadecyldimethylchlorosilane, octadecylmethyldichlorosilane, octadecylmethoxydichlorosilane, 7-octenyl dimethylchlorosilane, 7-octenyl trichlorosilane, 7-octenyl trimethoxysilane, octylmethyldichlorosilane, octyldimethylchlorosilane, octyltrichlorosilane, 10-undecynyldimethylchlorosilane, undecyltrichlorosilane, vinyldimethylchlorosilane, methyloctadecyldimethoxysilane, methyldodecyldiethoxysilane, methyloctadecyldimethoxysilane, methyloctadecyldiethoxysilane, n-octylmethyldimethoxysilane, n-octylmethyldiethoxysilane, triaconttyldimethylchlorosilane, triaconttyltrichlorosilane, methyltrimethoxysilane, methyltriethoxysilane, methyltri-n-propoxysilane, methylisopropoxysilane, methyl n-butyloxysilane, methyltri-sec-butyloxysilane, methyltri-t-butyloxysilane, ethyltrimethoxysilane, ethyltriethoxysilane, ethyltri-n-propoxysilane, ethylisopropoxysilane, ethyl-n-butyloxysilane, ethyltri-sec-butyloxysilane, ethyltri-t-butyloxysilane, n-propyltrimethoxysilane, isobutyltrimethoxysilane, n-hexyltrimethoxysilane, hexadecyltrimethoxysilane, n-octyltrimethoxysilane, n-dodecyltrimethoxysilane, n-octadecyltrimethoxysilane, n-propyltriethoxysilane, isobutyltriethoxysilane, n-hexyltriethoxysilane, hexadecyltriethoxysilane, n-octyltriethoxysilane, n-dodecyltrimethoxysilane, n-octadecyltriethoxysilane, 2-[2-(trichlorosilyl)ethyl]pyridine, 4-[2-(trichlorosilyl)ethyl]pyridine, diphenyldimethoxysilane, diphenyldiethoxysilane, 1,3-(trichlorosilylmethyl)heptacosane, dibenzyldimethoxysilane, dibenzyldiethoxysilane, phenyltrimethoxysilane, phenylmethyldimethoxysilane, phenyldimethylmethoxysilane, phenyldimethoxysilane, phenyldiethoxysilane, phenylmethyldiethoxysilane, phenyldimethylethoxysilane, benzyltriethoxysilane, benzyltrimethoxysilane, benzylmethyldimethoxysilane, benzyldimethylmethoxysilane, benzyldimethoxysilane, benzyldiethoxysilane, benzylmethyldiethoxysilane, benzyldimethylethoxysilane, benzyltriethoxysilane, dibenzyldimethoxysilane, dibenzyldiethoxysilane, 3-acetoxypropyltrimethoxysilane, 3-acryloxypropyltrimethoxysilane, aryltrimethoxysilane, aryltriethoxysilane, 4-aminobutyltriethoxysilane, (aminoethylaminomethyl)phenethyltrimethoxysilane, N-(2-aminoethyl)-3-aminopropylmethyldimethoxysilane, N-(2-aminoethyl)-3-aminopropyltrimethoxysilane, 6-(aminohexylaminopropyl)trimethoxysilane, p-aminophenyltrimethoxysilane, p-aminophenylethoxysilane, m-aminophenyltrimethoxysilane, m-aminophenylethoxysilane, 3-aminopropyltrimethoxysilane, 3-aminopropyltriethoxysilane, ω-aminoundecyltrimethoxysilane, amyltriethoxysilane, benzoxasilepin dimethylester, 5-(bicycloheptenyl)triethoxysilane, bis(2-hydroxyethyl)-3-aminopropyltriethoxysilane, 8-bromooctyltrimethoxysilane, bromophenyltrimethoxysilane, 3-bromopropyltrimethoxysilane, n-butyltrimethoxysilane, 2-chloromethyltriethoxysilane, chloromethylmethyldiethoxysilane, chloromethylmethyldiisopropxysilane, p-(chloromethyl)phenyltrimethoxysilane, chloromethyltriethoxysilane, chlorophenyltriethoxysilane, 3-chloropropylmethyldimethoxysilane, 3-chloropropyltriethoxysilane, 3-chloropropyltrimethoxysilane, 2-(4-chlorosulfonylphenyl)ethyltrimethoxysilane, 2-cyanoethyltriethoxysilane, 2-cyanoethyltrimethoxysilane, cyanomethylphenethyltriethoxysilane, 3-cyanopropyltriethoxysilane, 2-(3-cyclohexenyl)ethyltrimethoxysilane, 2-(3-cyclohexenyl)ethyltriethoxysilane, 3-cyclohexenyltrichlorosilane, 2-(3-cyclohexenyl)ethyltrichlorosilane, 2-(3-cyclohexenyl)ethyldimethylchlorosilane, 2-(3-cyclohexenyl)ethylmethyldichlorosilane, cyclohexyldimethylchlorosilane, cyclohexylethyldimethoxysilane, cyclohexylmethyldichlorosilane, cyclohexylmethyldimethoxysilane, (cyclohexylmethyl)trichlorosilane, cyclohexyltrichlorosilane, cyclohexyltrimethoxysilane, cyclooctyltrichlorosilane, (4-cyclooctenyl)trichlorosilane, cyclopentyltrichlorosilane, cyclopentyltrimethoxysilane, and 1,1-diethoxy-1-silacyclopenta-3-ene.

Additionally, there may be mentioned 3-(2,4-dinitrophenylamino)propyltriethoxysilane, (dimethylchlorosilyl)methyl-7,7-dimethylnorpinane, (cyclohexylaminomethyl)methyldiethoxysilane, (3-cyclopentadienylpropyl)triethoxysilane, (N,N-diethyl-3-aminopropyl)trimethoxysilane, 2-(3,4-epoxycyclohexyl)ethyltrimethoxysilane, 2-(3,4-epoxycyclohexyl)ethyltriethoxysilane, (furfuryloxymethyl)triethoxysilane, 2-hydroxy-4-(3-triethoxypropoxy)diphenylketone, 3-(p-methoxyphenyl)propylmethyldichlorosilane, 3-(p-methoxyphenyl)propyltrichlorosilane, p-(methylphenethyl)methyldichlorosilane, p-(methylphenethyl)trichlorosilane, p-(methylphenethyl)dimethylchlorosilane, 3-morpholinopropyltrimethoxysilane, (3-glycidoxypropyl)methyldiethoxysilane, 3-glycidoxypropyltrimethoxysilane, 1,2,3,4,7,7,-hexachloro-6-methyldiethoxysilyl-2-norbornene, 1,2,3,4,7,7,-hexachloro-6-triethoxysilyl-2-norbornene, 3-iodo propyltrimethoxysilane, 3-isocyanatepropyltriethoxysilane, (mercaptomethyl)methyldiethoxysilane, 3-mercaptopropylmethyldimethoxysilane, 3-mercaptopropyldimethoxysilane, 3-mercaptopropyltriethoxysilane, 3-methacryloxypropylmethyldiethoxysilane, 3-methacryloxypropyltrimethoxysilane, methyl{2-(3-trimethoxysilylpropylamino)ethylamino}-3-propyonate, 7-octenyltrimethoxysilane, R—N-α-phenethyl-N′-triethoxysilylpropylurea, S—N-α-phenethyl-N′-triethoxysilylpropylurea, phenethyltrimethoxysilane, phenethylmethyldimethoxysilane, phenethyldimethylmethoxysilane, phenethyldimethoxysilane, phenethyldiethoxysilane, phenethylmethyldiethoxysilane, phenethyldimethylethoxysilane, phenethyltriethoxysilane, (3-phenylpropyl)dimethylchlorosilane, (3-phenylpropyl)methyldichlorosilane, N-phenylaminopropyltrimethoxysilane, N-(triethoxysilylpropyl)dansylamide, N-(3-triethoxysilylpropyl)-4,5-dihydroimidazole, 2-(triethoxysilylethyl)-5-(chloroacetoxy)bicycloheptane, (S)—N-triethoxysilylpropyl-o-menthocarbamate, 3-(triethoxysilylpropyl)-p-nitrobenzamide, 3-(triethoxysilyl)propylsaccinic anhydride, N-[5-(trimethoxysilyl)-2-aza-1-oxo-pentyl]caprolactam, 2-(trimethoxysilylethyl)pyridine, N-(trimethoxysilylethyl)benzyl-N,N,N-trimethylammoniumchloride, phenylvinyldiethoxysilane, 3-thiocyanatepropyltriethoxysilane, (tridecafluoro-1,1,2,2,-tetrahydrooctyl)triethoxysilane, N-{3-(triethoxysilyl)propyl}phthalamic acid, (3,3,3-trifluoropropyl)methyldimethoxysilane, (3,3,3-trifluoropropyl)trimethoxysilane, 1-trimethoxysilyl-2-(chloromethyl)phenylethane, 2-(trimethoxysilyl)ethylphenylsulfonylazide, β-trimethoxysilylethyl-2-pyridine, trimethoxysilylpropyldiethylenetriamine, N-(3-trimethoxysilylpropyl)pyrrole, N-trimethoxysilylpropyl-N,N,N-tributylammoniumbromide, N-trimethoxysilylpropyl-N,N,N-tributylammoniumchloride, N-trimethoxysilylpropyl-N,N,N-trimethylammoniumchloride, vinylmethyldiethoxysilane, vinyltriethoxysilane, vinyltrimethoxysilane, vinylmethyldimethoxysilane, vinyldimethylmethoxysilane, vinyldimethylethoxysilane, vinylmethyldichlorosilane, vinylphenyldichlorosilane, vinylphenyldiethoxysilane, vinylphenyldimethylsilane, vinylphenylmethylchlorosilane, vinyltris-t-butoxysilane, adamantylethyltrichlorosilane, arylphenyltrichlorosilane, (aminoethylaminomethyl)phenethyltrimethoxysilane, 3-aminophenoxydimethylvinylsilane, phenyltrichlorosilane, phenyldimethylchlorosilane, phenylmethyldichlorosilane, benzyltrichlorosilane, benzyldimethylchlorosilane, benzylmethyldichlorosilane, phenethyldiisopropylchlorosilane, phenethyltrichlorosilane, phenethyldimethylchlorosilane, phenethylmethyldichlorosilane, 5-(bicycloheptenyl)trichlorosilane, 5-(bicycloheptenyl)triethoxysilane, 2-(bicycloheptyl)dimethylchlorosilane, 2-(bicycloheptyl)trichlorosilane, 1,4-bis(trimethoxysilylethyl)benzene, bromophenyltrichlorosilane, 3-phenoxypropyldimethylchlorosilane, 3-phenoxypropyltrichlorosilane, t-butylphenylchlorosilane, t-butylphenylmethoxysilane, t-butylphenyldichlorosilane, p-(t-butyl)phenethyldimethylchlorosilane, p-(t-butyl)phenethyltrichlorosilane, 1,3-(chlorodimethylsilylmethyl)heptacosane, ((chloromethyl)phenylethyl)dimethylchlorosilane, ((chloromethyl)phenylethyl)methyldichlorosilane, ((chloromethyl)phenylethyl)trichlorosilane, ((chloromethyl)phenylethyl)trimethoxysilane, chlorophenyltrichlorosilane, 2-cyanoethyltrichlorosilane, 2-cyanoethylmethyldichlorosilane, 3-cyanopropylmethyldiethoxysilane, 3-cyanopropyldimethylethoxysilane, 3-cyanopropylmethyldichlorosilane, 3-cyanopropyltrichlorosilane, and the like.

Using any of the silane compounds as the lyophobic material enables formation of a self-assembled film made of the silane compound in an area where the compound is applied. Thus, a surface of the film formed can be made highly lyophobic.

Among the silane compounds, fluorine-containing alkyl silane compounds with a fluorine in an alkyl group directly bonding with Si, preferably, have a perfluoroalkyl structure CₙF₂ₙ₊₁. Examples of the fluorine-containing silane compounds can be expressed by a general formula (2) below.

CₙF₂ₙ₊₁(CH₂)ₘ SiX¹X²X³ (2)

In the formula (2), n represents an integer ranging from 1 to 18, and m represents an integer ranging from 2 to 6. Additionally, X¹ represents —OR² or —Cl; X² and X³ represent —OR², —R³, or —Cl; R² represents any of alkyl groups having 1 to 4 carbons; and R³ represents a hydrogen atom or any of the alkyl groups having 1 to 4 carbons. Furthermore, X¹, X², and X³ may be the same as or different from each other.

The alkoxy groups and the chlorine groups represented by —OR² are functional groups for forming the Si—O—Si bond, and hydrolyzed with water and desorbed as an alcohol or an acid. Examples of the alkoxy groups include a methoxy group, an ethoxy group, an n-propoxy group, an isopropoxy group, an n-butoxy group, an isobutoxy group, a sec-butoxy group, and a tert-butoxy group. Preferably, the alkoxy groups have 1 to 4 carbons, since desorbed alcohol molecules have a relatively small molecular weight and thus can be easily removed, thereby suppressing the density reduction of a film to be formed.

Using any of the fluorine-containing alkyl silane compounds enables formation of a self-assembled film by allowing each compound to be aligned such that a fluoroalkyl group is positioned on a film surface. Thereby, the film has a highly lyophobic surface.

More specifically, there may be mentioned CF₃—CH₂CH₂—Si(OCH₃)₃, CF₃(CF₂)₃—CH₂H₂—Si(OCH₃)₃, CF₃(CF₂)₅—CH₂CH₂—Si(OCH₃)₃, CF₃(CF₂)₅—CH₂CH₂—Si(OC₂H₅)₃, CF₃(CF₂)₇—CH₂CH₂—Si(OCH₃)₃, CF₃(CF₂)₁₁—CH₂CH₂—Si(OC₂H₅)₃, CF₃(CF₂)₃—CH₂CH₂—Si(CH₃)(OCH₃)₂, CF₃(CF₂)₇—CH₂CH₂—Si(CH₃)(OCH₃)₂, CF₃(CF₂)₈—CH₂CH₂—Si(CH₃)(OC₂H₅)₂, CF₃(CF₂)₈—CH₂CH₂—Si(C₂H₅)(OC₂H₅)₂, and the like.

Additionally, a fluororesin used as the lyophobic material is prepared by dissolving a predetermined amount of the fluororesin in a predetermined solvent. Specifically, there may be used a solution prepared by dissolving 0.1 wt % of fluororesin in a hydrofluoroether (HFE) solvent (“EGC-1720” manufactured by Sumitomo 3M Ltd.). In this case, a solution composed of alcohol, hydrocarbon, ketone, ether, or ester is mixed in the HFE solvent according to need. Thereby, an adjustment can be made such that the liquid material is stably discharged from the liquid droplet discharging head 301. Other than that, fluororesins to be used may be “lumiflon” (soluble in various kinds of solvents) manufactured by Asahi Glass Co., Ltd., “optool” (solvents: PFC, HFE, etc.) manufactured by Daikin Industries, Ltd., “dicguard” (solvents: toluene, water, and ethylene glycol) manufactured by Dainippon Ink & Chemicals, Inc., and the like. Additionally, it is also possible to use fluorine-containing resins having a fluoro group (F), —CF₃, or —(CF₂)ₙCF₃ at a side chain thereof, or —CF₂—, —CF₂CF₃, or —CF₂CFCl— at a main chain thereof. Furthermore, when heating and polymerization are required to provide a lyophobic property to the material, for example, according to need, a fluorine-containing resin applied is polymerized by heating at a temperature of 150 to 200° C. to make the resin lyophobic. The present embodiment uses octadecyltrimethoxysilane (ODS) as the lyophobic material.

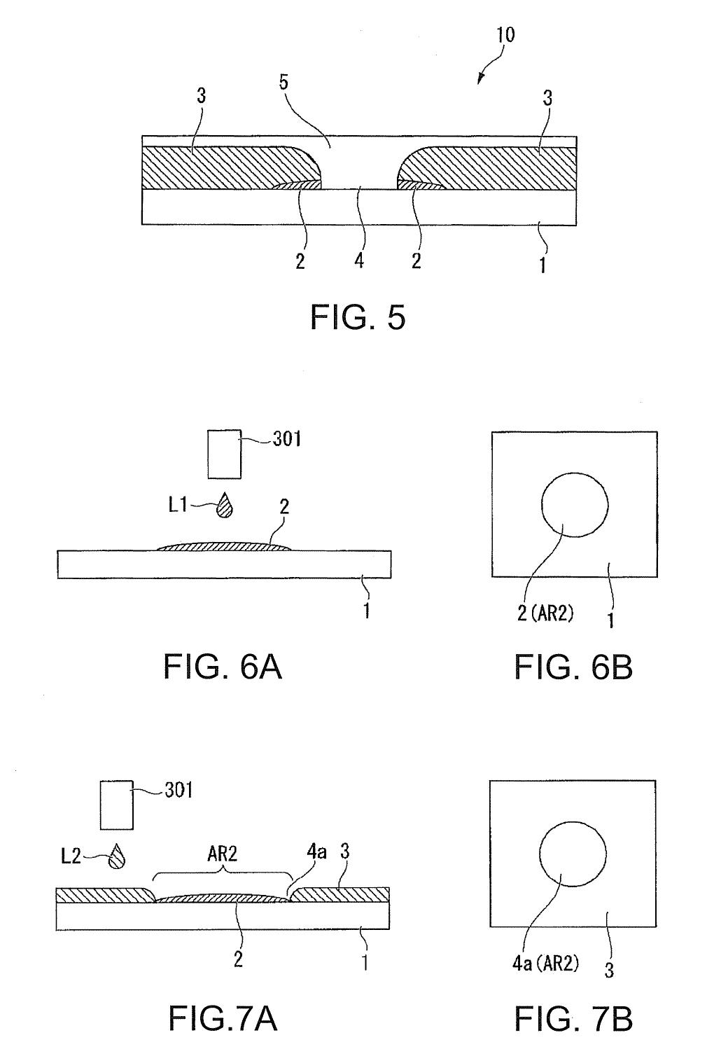

Based on the above description, the method for producing a multilayered wiring substrate according to the first embodiment will be described with reference to FIGS. 5 to 9. As a simplified example of the substrate, FIG. 5 shows a sectional view of a multilayered wiring substrate 10 having a first conductive layer and a second conductive layer connected to each other via a contact hole.

As shown in FIG. 5, the multilayered wiring substrate 10 includes a first conductive layer 1, a lyophobic area 2 formed on the first conductive layer 1 so as to cover the lyophobic area 2, a contact hole 4 formed in an insulating layer 3 in the lyophobic area 2, and a second conductive layer 5 electrically connected to the first conductive layer 1 via the contact hole 4.

The first and the second conductive layers 1 and 5 can have various shapes in accordance with a circuit structure, such as a belt-like wiring or a planar conductive pad. The conductive layers may be made of any of gold, silver, copper, palladium, nickel, and ITO, or any of oxides thereof, a conductive polymer, a superconductor, or the like. The present embodiment uses copper for the conductive layers.

On the first conductive layer 1 is formed the lyophobic area 2 covering a partial region of the layer. The lyophobic area 2 is made of a liquid containing any of the above-mentioned materials, namely, the lyophobic ink L1, which is applied by the liquid droplet discharging method.

The insulating layer 3 is formed so as to cover the first conductive layer 1 and the lyophobic area 2. A material of the insulating layer 3 in the embodiment includes a photo-curing material. Specifically, the photo-curing material used in the embodiment contains a photo-polymerization initiator and a monomer and/or an oligomer of acrylic acid. In general, the photo-curing material may be composed of a solvent and a resin dissolved in the solvent. For example, the photo-curing material may contain a photosensitive resin to increase a polymerization rate or may contain a resin and a photo-polymerization initiator for initiating curing of the resin. As an alternative to those examples, the photo-curing material may be composed of a monomer that is photo-polymerized to generate an insoluble insulating resin and a photo-polymerization initiator that initiates photo-polymerization of the monomer. However, when the monomer has a photo-functional group, no photo-polymerization initiator is needed to be contained in the material. A method for forming the insulating layer 3 will be described later.

On the insulating layer 3 is formed the contact hole 4 connected to the first conductive layer 1. The contact hole 4 is formed so as to penetrate through the insulating layer 3. A method for forming the contact hole 4 will be described later.

On the insulating layer 3 is formed the second conductive layer 5 that is connected to the first conductive layer 1 via the contact hole 4.

Next will be described the method for producing the multilayered wiring substrate 10 by referring to the drawings. FIGS. 6A to 9B are step views illustrating individual steps for producing the multilayered wiring substrate 10 shown in FIG. 5. In each of the drawings, drawing A is a sectional view and drawing B is a plan view.

First, as shown in FIG. 6A, the lyophobic ink L1 discharged from the liquid droplet discharging head 301 lands in a region including a region where the ink overlaps with a contact hole to be formed, namely, on a second area AR2, whereby the lyophobic ink L1 forms the lyophobic area 2 covering the second area AR2 on the first conductive layer 1. In the embodiment, the lyophobic ink L1 is applied by the liquid droplet discharging method, so that the lyophobic area 2 can be formed with a desired size and at an appropriate position. In FIG. 6B, the second area AR2 has a circular shape when viewed two-dimensionally, although the second area AR2 may have any other shape according to need, such as a square or rectangular shape. Additionally, it is also possible to reduce a discharging amount of the lyophobic ink L1 applied to form the second area AR2 in a smaller size. For example, when only a single droplet of the lyophobic ink L1 lands on the region, the ink L1 wettingly spreads in an approximately circular shape on a landing surface, thereby resulting in formation of the second area AR2 having a minute size. In FIG. 6B, the lyophobic area 2 is shown to have a certain degree of thickness, although, actually, the thickness of the area 2 is approximately a few to 100 nanometers.

Next, as shown in FIG. 7A, the insulating ink L2 is discharged from the liquid droplet discharging head 301 to be applied on a region of the first conductive layer 1 excluding the second area AR2. The insulating ink L2, which is repelled by the lyophobic area 2 formed on the second area AR2, is thus once located in the region except for the second area AR2 to be applied in such a manner that an opening portion 4a is formed in a region overlapping with the second area AR2. As shown in FIG. 7B, the insulating ink L2 is applied so as to surround a periphery of the second area AR2. Consequently, the insulating ink L2 can cover most of the region except for the region overlapping with the contact hole, so that forming the opening portion 4a can serve to approximately determine a position for forming the contact hole.

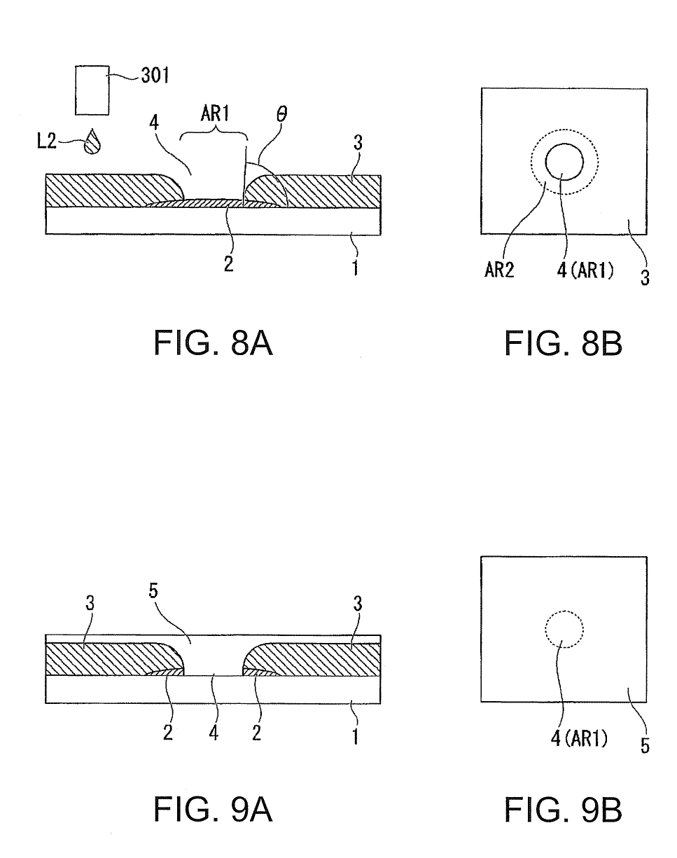

Then, as shown in FIG. 8A, the insulating ink L2 is further discharged from the liquid droplet discharging head 301 to be additionally applied. This increases a thickness of the insulating ink L2, resulting in deformation of the ink due to a weight of the ink. The deformation causes a contact angle between the insulating ink L2 applied and the lyophobic area 2 to reach a forward contact angle therebetween. Thereafter, the insulating ink L2, which is against the lyophobic property of the lyophobic area 2, wettingly spreads inside the second area AR2. The insulating ink L2 is applied until the wettingly spread ink covers an intended part of the second area AR2, and then, a predetermined light-irradiation is performed to cure the insulating ink L2 so as to form the insulating layer 3 having the contact hole 4 with an intended opening diameter (a first area AR1). As shown in FIG. 8B, the insulating ink L2 wettingly spreads isotropically toward a center of the second area AR2 from the periphery of the area. Accordingly, the first area AR1 is formed near the center of the second area AR2. In this manner, the contact hole 4 can be formed with an opening diameter smaller than that of the second area AR2 having the lyophobic area formed thereon. Additionally, forming the first area AR1 at the center of the second area AR2 enables formation of the contact hole 4 with a high positional precision.

Next, as shown in FIG. 9A, on an upper surface of the contact hole 4 and the insulating layer 3 is arranged a conductive material to form the second conductive layer 5. For example, a conductive-material containing functional liquid is applied in a predetermined region of the contact hole 4 and the insulating layer 3 by the above-described liquid droplet discharging method to form the second conductive layer 5. The lyophobic area 2 has the minute thickness ranging from approximately a few to 100 nanometers. Thus, a partial decomposition of the lyophobic area 2 due to a heating processing for forming a wiring pattern described below or a reaction such as fusion between microparticles allows the first conductive layer 1 to be formed so as to secure conductivity with the second conductive layer 5 via the contact hole 4. As shown in FIG. 9B, after forming the second conductive layer 5, the first and the second conductive layers 1 and 5 are connected to each other via the contact hole 4 whose opening diameter size is equal to a size of the first area AR1.

The conductive-material containing functional liquid may be a dispersion liquid obtained by dissolving conductive microparticles containing any of gold, silver, copper, palladium, nickel, ITO, any of oxides thereof, a conductive polymer, or a superconductor in a dispersion medium. In order to increase dispersibility, surfaces of those conductive microparticles may be coated with an organic substance or the like.

The dispersion medium is not restricted to a specific one, as long as the medium can disperse the conductive microparticles as mentioned above without causing aggregation. For example, besides water, there may be mentioned an alcohol such as methanol, ethanol, propanol or butanol, a hydrocarbon compound such as n-heptane, n-oxtane, decane, dodecane, tetradecane, toluene, xylene, cymene, durene, indene, dipentene, tetrahydronaphthalene, decahydronaphthalene or cyclohexylbenzene, an ether compound such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxy ethane, bis(2-methoxy ethyl)ether, or p-dioxane, or a polar compound such as propylene carbonate, γ-butyrolactone, N-methyl-2-pyrrolidone, dimethyl formamide, dimethyl sulfoxide, or cyclohexanone. Among them, water, the alcohols, the hydrocarbons, and the ether compounds are more preferable in terms of the dispersibility of microparticles, the stability of a dispersion liquid, and easier applicability to the inkjet method. Particularly, water and the hydrocarbon compounds are more preferable dispersion media.

After placing a droplet of the function liquid containing any of the conductive materials as described above, thermal treatment and/or optical treatment processing is performed to remove the dispersion medium and a coating agent contained in the droplet of the functional liquid to form the second conductive layer 5. Specifically, removing the dispersion medium included in the functional liquid placed allows the conductive microparticles to be contacted or fused with each other, thereby forming a wiring. When the surfaces of the conductive microparticles are coated with the coating agent such as an organic substance to increase dispersibility, the coating agent is also removed. In the present embodiment, a thermal processing is performed by heating using an electrical furnace (not shown), so as to form the second conductive layer 5.

Usually, the thermal treatment and/or the optical treatment are performed in an air atmosphere. However, if needed, the treatments may be performed in an atmosphere with an inert gas such as nitrogen, argon, or helium. A temperature for the treatments is appropriately determined in consideration of a boiling point (a vapor pressure) of the dispersion medium, a kind and a pressure of an atmospheric gas, thermal behaviors of the microparticles such as dispersibility and oxidizability, a presence or an absence of the coating agent, an amount of the coating agent, a heat-resistant temperature of a base material, and the like.

For example, removal of the coating agent made of any organic agent requires firing at approximately 300° C. In a case of a plastic substrate, a preferable temperature for firing is in a range of a room temperature to 100° C.

The heat treatment and/or the optical treatment may be performed by lamp annealing, other than ordinary heating treatments using a heater such as a hot plate or an electrical furnace. A light source used for the lamp annealing is not specifically restricted. For example, there may be used an infrared lamp, a xenon lamp, a YAG laser, an argon laser, a carbon dioxide gas laser, or an excimer laser such as XeF, XeCl, XeBr, KrF, KrCl, ArF, or ArCl. Those light sources generally have an output range of 10 W to 5,000 W, although the embodiment can be sufficiently achieved in a range of 100 W to 1,000 W. The above-described thermal treatment and/or the optical treatment secure electrical contact between the microparticles, thereby enabling the formation of the second conductive layer 5. This results in completion of the multilayered wiring substrate 10 having the first and the second conductive layers connected to each other via the contact hole.

In the method for producing the multilayered wiring substrate 10 structured as above, first, the position of the contact hole 4 is accurately determined in accordance with the position of the lyophobic area 2. Then, the insulating ink L2 is applied such that the contact angle between the insulating ink L2 and the lyophobic area 2 is larger than the forward contact angle therebetween, which can control the size of the first area AR1. This enables the contact hole 4 smaller than the lyophobic area 2 to be easily formed. Accordingly, in the multilayered wiring substrate 10 thus produced, the position and the size of the contact hole 4 can be accurately controlled.

Additionally, in the embodiment, the liquid droplet discharging method is used to apply the lyophobic ink L1 so as to form the lyophobic area 2. This can facilitate the formation of the lyophobic area 2 having the minute size, thereby enabling formation of the contact hole 4 having a minute size.

Additionally, in the embodiment, when forming the insulating layer 3, controlling an amount of the insulating ink L2 applied enables control of the size of the first area AR1. The applying amount of the insulating ink L2 can be precisely controlled by using advantages of the liquid droplet discharging method capable of precisely adjusting the applying amount thereof. Therefore, the insulating ink L2 can be easily applied such that the contact angle of the ink L2 applied is larger than the forward contact angle thereof, thereby facilitating formation of the contact hole 4.

Additionally, in the embodiment, the lyophobic area 2 is composed of ODS, which is the silane compound that forms a self-assembled film on a surface where the compound is applied. Using ODS can sufficiently secure the lyophobic property required for the liquid material, thereby resulting in a favorable formation of the lyophobic area 2,. Additionally, when the lyophobic material composed of ODS is applied on the surface, ODS immediately forms a monomolecular film on the surface due to a self-assembly property thereof, thereby expressing a highly lyophobic property. Consequently, the formation of the lyophobic area 2 can be facilitated.

Additionally, in the embodiment, the insulating layer 3 is composed of a photo-curing resin. The photo-curing resin generally has a small curing shrinkage ratio, thereby facilitating formation of the contact hole 4 having a desired shape. Furthermore, a short-time light-irradiation causes curing of the resin. This can prevent flowing of the insulating-layer forming material and thereby deformation of the shape of the material during the curing, so that the shape and the size of the contact hole 4 can be controlled with a high precision. Moreover, the short-time light-irradiation causes resin curing, thereby forming the contact hole 4. Thus, as compared to a thermal curing resin, the photo-curing resin provides a high work efficiency, thereby improving productivity.

The lyophobic material used in the embodiment is ODS as the silane compound forming a self-assembled film as described above. However, the lyophobic material may be a high polymer precursor included in the lyophobic area 2. An example of the precursor is a fluorocarbon resin. In that case, preferably, the formation of the lyophobic area 2 includes heating and polymerization of the lyophobic material applied. In this manner, heating and polymerizing the fluorocarbon resin can further ensure expression of the lyophobic property.

Additionally, in the embodiment, the size of the first area AR1 is controlled by controlling the applying amount of the insulating ink L2. Alternatively, controlling a temperature of the insulating ink L2 may enable control of the size of the first area AR1. The forward contact angle of a liquid is changed in accordance with the temperature of a liquid. As the temperature of the liquid increases, the forward contact angle thereof becomes smaller, whereas as the temperature of the liquid decreases, the forward contact angle thereof becomes larger. Accordingly, a value of the forward contact angle is changed when increasing the temperature of the insulating ink L2 placed at the contact angle θ. Then, when the contact angle θ becomes equal to or larger than the forward contact angle, the ink begins to flow. This can control the flow of the insulating ink L2 to the inside of the second area AR2. Alternatively, the size of the first area AR1 may be controlled by simultaneously controlling both the applying amount and the temperature of the insulating ink L2.

### Multilayered Wiring Substrate

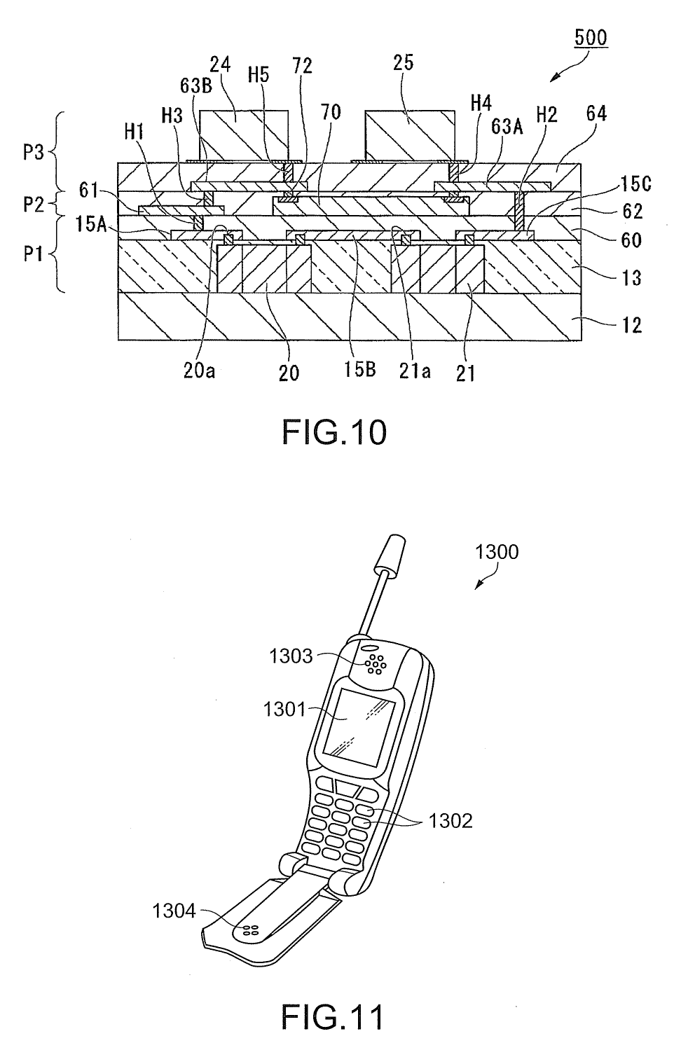

Next will be described a multilayered wiring substrate produced by the above producing method by referring to FIG. 10. Hereinafter, a multilayered wiring substrate 500 will be described as an example incorporated in a mobile phone. The multilayered wiring substrate 500 shown in FIG. 10 includes three wiring layers P1, P2, and P3 laminated on a base member 12 made of silicon. In the description below, a laminating direction of each wiring layer is an upper direction, and an arranging direction of the base member 12 is a lower direction, so as to indicate upper and lower relationships among constituent members.

Other than silicon, the base member 12 may be made of a glass plate, a quartz glass plate, a metal plate, or the like. Additionally, the base member 12 may have an underlayer made of a semiconductor film, a metal film, an insulating film, an organic layer, or the like formed on a surface of a substrate made of any of those materials.

The wiring layer P1 includes an insulating layer 13 formed on the substrate 12, a resistor 20 and a capacitor 21 that are embedded in the insulating layer 13 on the substrate 12, wirings 15A, 15B, and 15C that are connected to the resistor 20 and the capacitor 21, and a first interlayer insulating film (an insulating layer) 60 that is formed on the insulating layer 13 to cover the wirings.

The resistor 20 arranged on the substrate 12 includes two electrodes 20a, which are formed on an upper surface of the resistor 20. Like the resistor 20, the capacitor 21 arranged on the substrate 12 includes two electrodes 21a, which are formed on an upper surface of the capacitor 21.

Actually, the electrodes 20a and 21a, respectively, are formed without scarcely protruding from respective upper surfaces of the resistor 20 and the capacitor 21, although the electrodes are protruded in FIG. 10. Alternatively, a conductive material may be discharged by the liquid droplet discharging method or the like to actually form such a protrusion.

On a periphery of and the upper surface of each of the resistor 20 and the capacitor 21 on the upper surface of the substrate 12 is formed the insulating layer 13. The insulating layer 13 is formed by applying a photo-curing insulating ink by the liquid droplet discharging method and then curing the insulating ink applied.

On an upper surface of the insulating layer 13 are formed the wirings 15A, 15B, and 15C. Those wirings are formed by applying a conductive-material containing functional liquid by the liquid droplet discharging method. The conductive material used in the present embodiment is a functional liquid containing microparticles of silver. Among the wirings 15A to 15C, a first end of the wiring 15B is connected to one of the electrodes 20a and a second end thereof is connected to one of the electrodes 21a to electrically connect the resistor 20 to the capacitor 21. A first end of the wiring 15A is connected to the other one of the electrodes 20a, and a first end of the wiring 15C is connected to the other one of the electrodes 21a.

On the upper surface of the insulating layer 13 is formed the first interlayer insulating film 60 covering the wirings 15A to 15C. Like the insulating layer 13, the first interlayer insulating film 60 is formed by applying the photo-curing insulating ink by the liquid droplet discharging method and then curing the insulating ink applied.

The first interlayer insulating film 60 has a first contact hole H1 connected to the wiring 15A and a second contact hole H2 connected to a wiring 15C. Those contact holes are filled with the same material as the material for forming the wirings.

The wiring P2 includes a semiconductor chip 70, a wiring 61, which are both arranged on the first interlayer insulating film 60, and a second interlayer insulating film 62 arranged on the first interlayer insulating film 60 so as to cover the IC chip 70 and the wiring 61. On an upper surface of the semiconductor chip 70 on the first interlayer insulating film 60 are provided externally connecting terminals 72.

The wiring 61 on the first interlayer insulating film 60 is connected to the first contact hole H1. The wiring 61 is made of a conductive material applied by the liquid droplet discharging method, as are the wirings 15A, 15B, and 15C. Additionally, the wiring 61 is made of the same material as that of the three wirings.

On an upper surface of the first interlayer insulating film 60 is formed the second interlayer insulating film 62 to cover the wiring 61 and the semiconductor chip 70. The second interlayer insulating film 62 is formed by curing a photo-curing insulating ink applied by the liquid droplet discharging method, as are the insulating layer 13 and the first interlayer insulating film 60.

The second interlayer insulating film 62 has a third contact hole H3 that penetrates through the film 62 to be connected to the wiring 61 and a part of the second contact hole H2 that penetrates through the film 62 as is the third contact hole H3. Those contact holes are filled with the same material as that of the wirings.

The wiring layer P3 includes a wiring 63A and a wiring 63B formed on the second interlayer insulating film 62, a third interlayer insulating film 64 formed on the second interlayer insulating film 62 to cover the wirings 63A and 63B, an antenna terminal, and a crystal resonator 25 that are both arranged on the third interlayer insulating film 64.

The wiring 63A on the second interlayer insulating film 62 is connected to the wiring 15C via the second contact hole H2. The wiring 63A is connected to one of the terminals 72 of the semiconductor chip 70. Thereby, the semiconductor chip 70 is connected to the capacitor 21 via the wiring 63A, the second contact hole H2, and the wiring 15C.

The wiring 63B on the second interlayer insulating film 62 is connected to the wiring 61 via the third contact hole H3. The wiring 63B is connected to the other externally connecting terminal 72 of the semiconductor chip 70. Thereby, the semiconductor 70 is connected to the resistor 20 via the wiring 63B, the third contact hole H3, the wiring 61, and the first contact hole H1.

The wirings 63A and 63B are made of the conductive material applied by the liquid droplet discharging method. The conductive material of the wirings 63A and 63B is the same as that of the wirings 15A to 15C and 61.

The third interlayer insulating film 64 has a fourth contact hole H4 that penetrates through the third interlayer insulating film 64 to connect the wiring 63A to the crystal resonator 25, and a fifth contact hole H5 that penetrates through the third interlayer insulating film 64, as is the fourth contact hole H4, to connect the wiring 63B to the antenna element 24. The contact holes are filled with the same material as that of the wirings.

The contact holes H1 to H5 of the multilayered wiring substrate 500 thus structured are formed by using the contact hole forming method described above. Accordingly, in the multilayered wiring substrate 500, each contact hole can be formed with a high positional precision. Additionally, making the first area small and forming the contact holes each having a small opening diameter enables production of the multilayered wiring substrate 500 where the individual layers are electrically connected to each other via the minute contact holes.

### Electronic Apparatus

FIG. 11 is a perspective structural view of a mobile phone shown as an example of an electronic apparatus including the multilayered wiring substrate according to the above embodiment. A mobile phone 1300 includes a small display section 1301 as a liquid crystal device incorporating the multilayered wiring substrate of the embodiment, a plurality of operating buttons 1302, an earpiece 1303, and a microphone 1304.

The mobile phone 1300 of the embodiment uses the multilayered wiring substrate having the conductive layers connected to each other via the minute contact holes. This results in use of a high-density packaging substrate, so that the mobile phone 1300 can be produced as an entirely miniaturized electronic apparatus.

Other than the mobile phone as above, the multilayered wiring substrate of the embodiment can be suitably used in electronic apparatuses including electronic books, personal computers, digital still cameras, liquid crystal televisions, projectors, video tape recorders of viewfinder types or monitor viewing types, car-navigation devices, pagers, electronic notebooks, electric calculators, word processors, work stations, video phones, point-of-sale (POS) terminals, and apparatuses equipped with a touch panel. Using the high-density wiring substrate enables miniaturization of the electronic apparatuses. Additionally, using the highly integrated wiring substrate enables the electronic apparatuses to have higher calculation capabilities.

Hereinabove, although some preferred embodiments according to the invention have been described with reference to the accompanying drawings, it should be understood that the invention is not restricted to those embodiments. The shapes and the combinations of the constituent members used in the above-described embodiments are examples. Thus, various modifications and alterations can be made based on designing requirements and the like, without departing from the spirit and scope of the invention.

What is claimed is:

1. A method for producing a multilayered wiring substrate, comprising:
forming a lyophobic area on a first conductive layer;
forming an insulating layer with an opening portion on the first conductive layer by applying a functional liquid containing an insulating layer forming material on a periphery of the lyophobic area;
laminating the first conductive layer and a second conductive layer via the insulating layer; and
electrically connecting the first and the second conductive layers to each other via the opening portion of the insulating layer,
wherein when forming the insulating layer, the functional liquid is applied such that an angle of a portion of the functional liquid in contact with the lyophobic area becomes larger than a forward contact angle of the functional liquid, thereby allowing a position of the portion of the functional liquid in contact with the lyophobic area to move inside the lyophobic area to form the opening portion having an opening size smaller than a size of the lyophobic area.

2. The method for producing a multilayered wiring substrate according to claim 1, wherein the lyophobic area is formed by a liquid droplet discharging method.

3. The method for producing a multilayered wiring substrate according to claim 1, wherein when forming the insulating layer, an applying amount of the functional liquid controls the angle of the portion of the functional liquid in contact with the lyophobic area.

4. The method for producing a multilayered wiring substrate according to claim 1, wherein when forming the insulating layer, the functional liquid is heated to control the angle of the portion of the functional liquid in contact with the lyophobic area.

5. The method for producing a multilayered wiring substrate according to claim 1, wherein the lyophobic material includes at least one of a silane-containing compound and a fluoroalkyl-containing compound.

6. The method for producing a multilayered wiring substrate according to claim 5, wherein the lyophobic material forms a self-assembled film on a surface where the lyophobic material is located.

7. The method for producing a multilayered wiring substrate according to claim 5, wherein the lyophobic material is a polymeric precursor that includes the lyophobic area, and the formation of the lyophobic area includes heating and polymerizing the lyophobic material.

8. The method for producing a multilayered wiring substrate according to claim 1, wherein the insulating-layer forming material is a photo-curing resin.

9. A multilayered wiring substrate, comprising:
a first conductive layer having a lyophobic area formed thereon;
a second conductive layer electrically connected to the first conductive layer via a contact hole; and
an insulating layer having the contact hole formed therein, wherein the contact hole is located on the lyophobic area of the first conductive layer and has an opening size smaller than a size of the lyophobic area, as well as an angle formed by a side wall of the contact hole and the lyophobic area includes an angle equal to a forward contact angle between a liquid containing an insulating-layer forming material and the lyophobic area.

10. An electronic apparatus comprising the multilayered wiring substrate according to claim 9.
